(19) United States
(12) Patent Application Publication
(10) Pub. No.: US 2025/0385220 A1
(43) Pub. Date: Dec. 18, 2025

(54) METHOD OF FORMING AN ELECTRICAL CONNECTION AND ELECTRICAL CONNECTION

(71) Applicant: Infineon Technologies AG, Neubiberg (DE)

(72) Inventors: Chan Lam Cha, Jasin (MY); Yi Jing Roy Teo, Muar (MY); Wenn Tze Ho, Melaka Tengah (MY); Hoe Jian Chong, Melaka (MY); Xavier Arokiasamy, Teluk Intan (MY); Chin Kee Leow, Melaka (MY); Mohd Kahar Bajuri, Melaka (MY); Rolando Pontillas Enverga, Barangay Batingan (PH); Samsun Paing, Melaka (MY)

(21) Appl. No.: 19/240,487

(22) Filed: Jun. 17, 2025

(30) Foreign Application Priority Data
Jun. 18, 2024 (DE) 102024117141.3

(51) Int. Cl. H01L 23/00

(52) U.S. Cl. CPC H01L 24/85; H01L 24/48; H01L 24/45; H01L 2224/45139; H01L 2224/45144; H01L 2224/45147; H01L 2224/48091; H01L 2224/4846; H01L 2224/48491; H01L 2224/85035; H01L 2224/85047

(57) ABSTRACT

A method of forming an electrical connection is provided. The method may include: forming a first foldback bond on a first contact element by bonding a first section of a first bonding wire to the first contact element; folding the first bonding wire to arrange a second section of the first bonding wire over the bonded first section; and pressing the second section onto the first section, bonding a third section of the first bonding wire to a second contact element, and bonding a fourth section of the first bonding wire onto the first foldback bond.

### TECHNICAL FIELD

Various embodiments relate generally to a method of forming an electrical connection and to an electrical connection.

### BACKGROUND

Latest developments regarding power semiconductors, in particular regarding SiC MOS and GaN, have led to a reduction in chip size, and related to this to smaller bond pads that have an up to 30% smaller size, while being intended for a higher current density. This leads to challenges regarding power interconnects on such small bond pads.

Current solder technology for clip attach has still not proven to be attachable on such small pads. Even though solder paste may possibly be usable on smaller pads, it may have issues regarding a contaminated pad or residues from cleaning.

### SUMMARY

A method of forming an electrical connection is provided. The method may include: forming a first foldback bond on a first contact element by bonding a first section of a first bonding wire to the first contact element, folding the first bonding wire to arrange a second section of the first bonding wire over the bonded first section, and pressing the second section onto the first section, bonding a third section of the first bonding wire to a second contact element, and bonding a fourth section of the first bonding wire onto the first foldback bond.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flow diagram of a method of forming a an electrical connection in accordance with various embodiments;

FIGS. 2A to 2F each show an electrical connection in accordance with various embodiments;

FIG. 3 illustrates a method of forming a an electrical connection in accordance with various embodiments; and

FIG. 4 shows a flow diagram of a method of forming a an electrical connection in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, electrical connections are provided that connect two contactelements (e. g., a chip contact pad, a contact portion of a leadframe, a lead, a clip, a contact area of a printed circuit board, and the like) easily by two or more bonding wires that are stacked upon each other, whereby a space required on the bonding elements for a high current value is minimized, for example to a surface area that has approximately the size that is required for a single bonding wire.

In various embodiments, a multi-loop connection may be formed between a first contact element and a second contact element may be provided from a single wire by a starting foldback bond on the first bonding element that provides a flat top surface for attaching another wire bond from the same wire thereto, and further wire bonds formed alternatingly between the first bonding element and the second element, wherein each of the further wire bonds is formed sufficiently flat to be used as a landing surface for successive wire bonds to be stacked up on the existing wire bonds.

In a case where a bonding wire is cut after forming two or more bonding connections, and a new wire is used for a subsequent bonding connection, the new bonding connection may be started by another foldback bond.

The bonding connection being formed alternatingly between the two contact elements may be referred to as cross-chain bonding or, as a descriptive term for the looped wires that may be arranged one above the other between the two contact elements, as rainbow bonding.

In various embodiments, two wires may be arranged to connect two contact elements (for example a chip contact pad and a lead or leadframe, or two chip contact pads). A cross-chain bonding may be enabled for example from a chip contact pad to a lead using a single free air ball formation and connecting the two bonding elements by multiple sections of the same wire in a single bond process. This bonding concept may resolve the space limitation issue.

In various embodiments, if two chip contact pads or other pressure sensitive bonding elements are to be connected, a padding element may be formed on the pressure sensitive bonding element, and the wire bond may be formed on top of the padding element. The padding element may be formed from a wire section, for example from a free air ball, with a flat top surface that is suitable for receiving a wire bond.

A chip contact element without the padding element that forms part of the cross-chain interval may for example be or include a bonding element that is not sensitive to the pressure that may be exerted during a bonding process that does not involve a free air ball, for example a lead, a leadframe, or a non sensitive bonding pad.

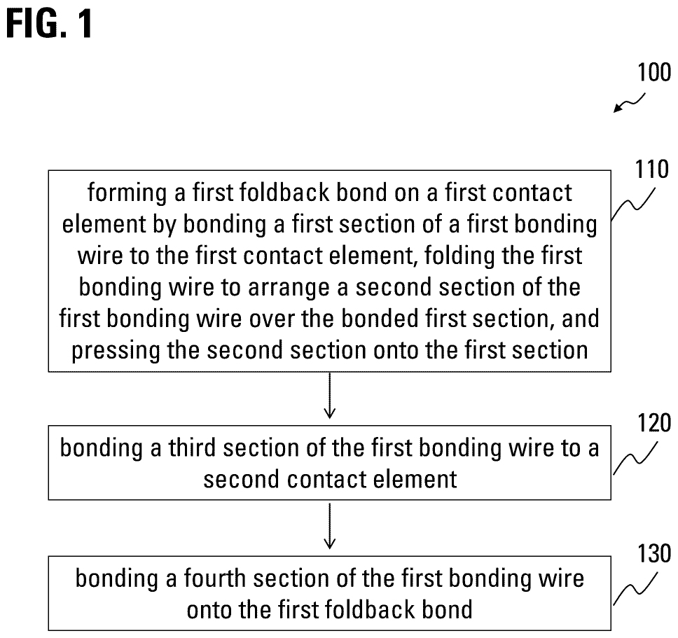

FIG. 1 shows a flow diagram 100 of a method of forming a an electrical connection in accordance with various embodiments.

The method includes forming a first foldback bond (also referred to as “ultra low loop”) on a first contact element by bonding a first section of a first bonding wire to the first contact element, folding the first bonding wire to arrange a second section of the first bonding wire over the bonded first section, and pressing the second section onto the first section (110), bonding a third section of the first bonding wire to a second contact element (120), and bonding a fourth section of the first bonding wire onto the first foldback bond (130).

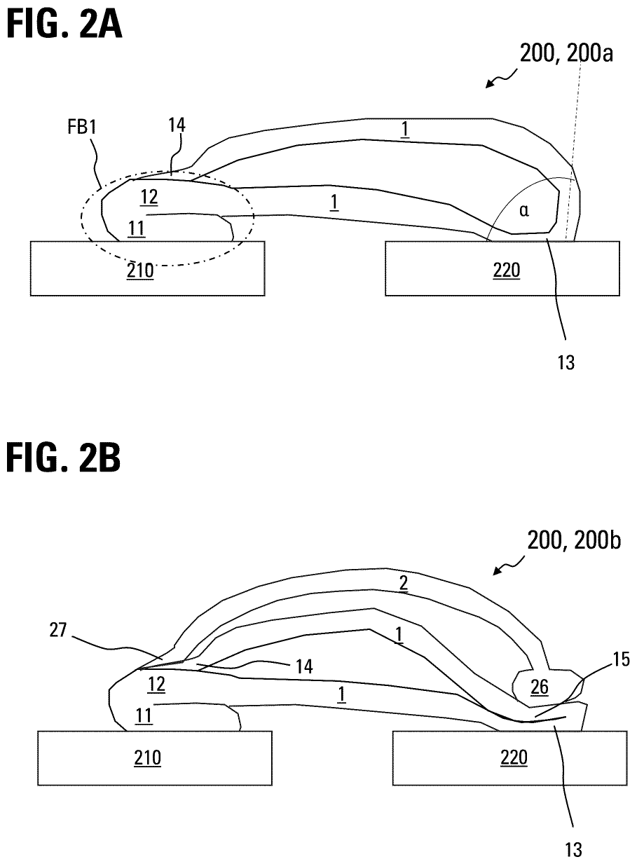

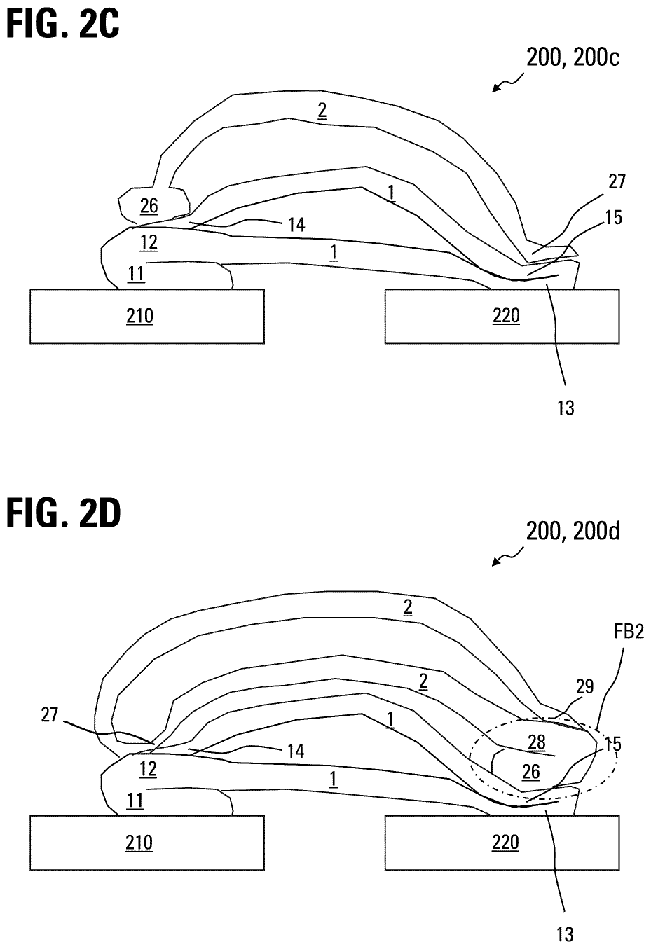

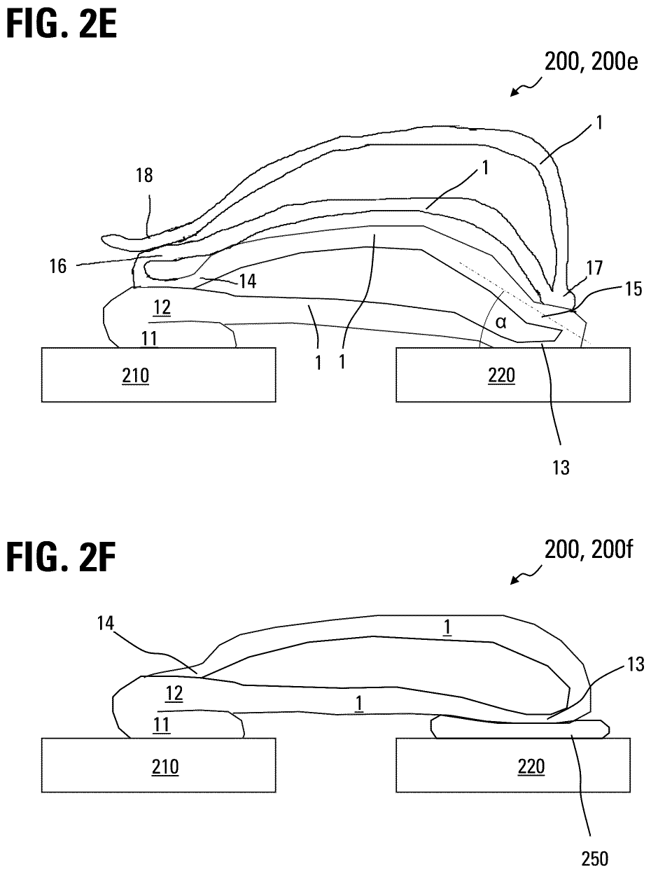

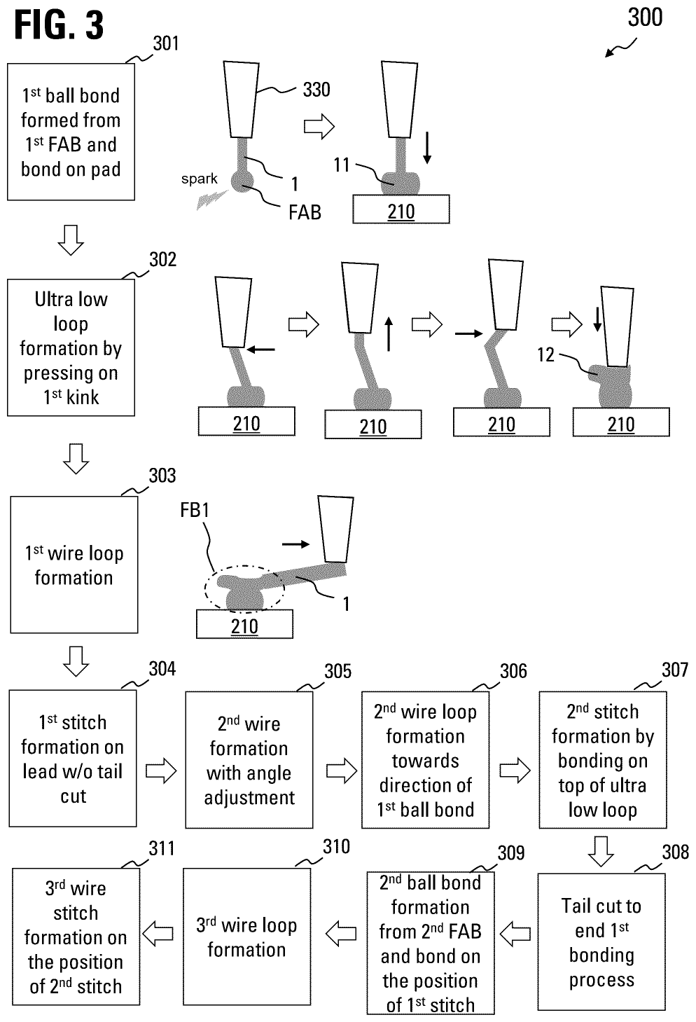

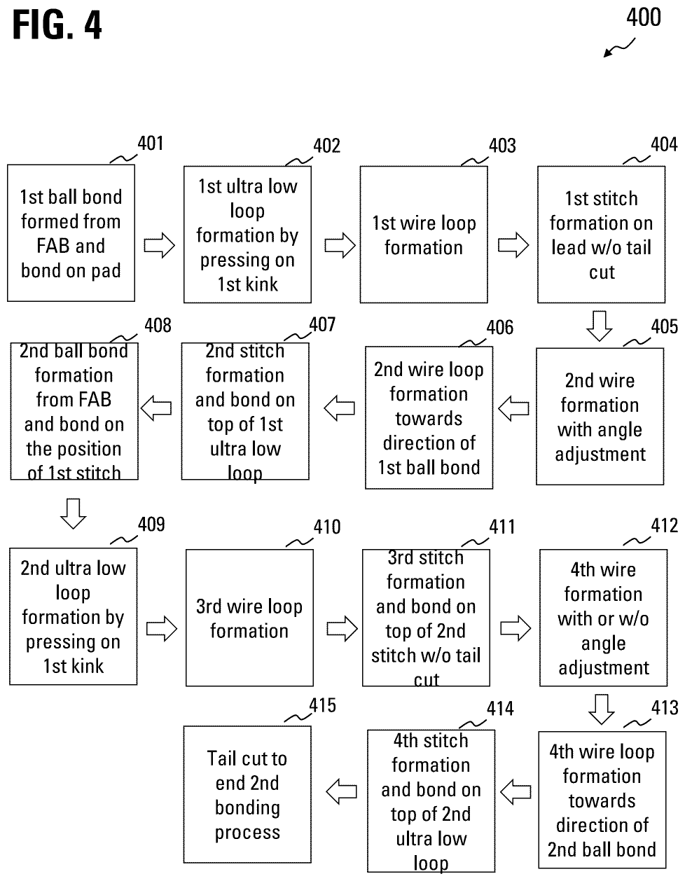

The method of FIG. 1 is illustrated in FIG. 3, in the sequence indicated by reference numbers 301 to 307 (with or without the angle adjustment in 305), and a resulting electrical connection 200, 200a is illustrated in FIG. 2A. The other embodiments of electrical connections 200 (200b to 200f) are also based on the method of FIG. 1, but may include additional aspects and/or processes that will be described in context with FIGS. 2B to 2F and FIG. 4.

The bonding processes described herein may in various embodiments include thermosonic or ultrasonic bonding.

As shown in FIG. 3, in Step 301, the forming the first foldback bond (the first ultra low loop) may include forming a first free air ball (FAB) on a first bonding wire 1 (wire 1 for short), for example on a tip of the first bonding wire 1. The first bonding wire 1 may be a bonding wire as typically used in the art, for example a bonding wire that includes or consists of aluminum, gold, an aluminum alloy or a gold alloy.

The first free air ball FAB may be bonded to a first contact element 210, for example by pressing with a bonding tool 330, for example an ultrasonic transducer that applies ultrasonic energy during the pressing, onto the first contact element 210 (301). The section of the first wire 1 that is attached directly to the first contact element 210 may be referred to as the first section 11.

The forming the first foldback bond (the first ultra low loop) may further include forming a first kink as shown in Step 302. The forming the first kink is illustrated in the second row of panels of FIG. 3 and may include pulling the bonding wire 1 to a first side direction (in FIG. 3 to the left) with the bonding tool 330 for decreasing an angle between the bonded free air ball FAB and the wire 1. Subsequently, the bonding tool 330 may be moved upward for releasing more of the wire 1, followed by a movement to a second side direction (in this case, to the right) that is opposite the first side direction, thereby forming a loop or a kink. The loop or kink may include a second section 12 of the first bonding wire 1 that is arranged vertically adjacent to the first section 11.

The forming the first foldback bond (the first ultra low loop) may further include pressing the bonding tool 330 onto the kink. Thereby, the ultra low loop/foldback bond (labelled with FB1 in FIG. 2A) may be completed (302).

Subsequently, a first wire 1 loop may be formed (303). The bonding tool 330 may release more of the first wire 1 to extend between the first contact element 210 and a second contact element 220 (see FIG. 2A).

Subsequently, a first bonding stitch may be formed on the second contact element 220 (e. g., on a lead or a leadframe) (304). The forming the first bonding stitch may for example include pressing a third section 13 of the first bonding wire 1 onto the second contact element 220, for example while applying ultrasonic energy and optionally heat.

The first bonding stitch is formed without a tail cut (in other words, leaving the first wire 1 attached to the first bonding stitch), in order to make possible that a loop back connection is completed in a single continuous bonding process.

Subsequently, the first wire 1, which is still attached to the first bonding stitch and the second contact element 220, may be brought back towards the first contact element 210. The first wire 1 may form more or less a right angle with a surface of the second contact element 220, for example as shown in FIG. 2A (the angle α may for example be in a range of between about 60° and 120° if an angle adjustment of process 305 is omitted and only the process 306 is executed), or a longitudinal axis of the first wire 1 may form an acute angle α (or even be essentially parallel, thus for example in a range from about 0° to about) 30° with the surface of the second contact element 220 (for example if both processes, 305 and 306, are executed). The angle adjustment may be performed similar to a process described above for the formation of the first foldback bond FB1, namely the pulling of the first wire 1 towards a side direction. The angle adjustment process may make a bond suitable, e. g. by creating a reasonably flat top surface, for receiving a further wire bond on its top surface.

In various embodiments, the method may further include forming a bond on the first foldback bond FB1. For example, a second stitch bond may be formed on top of the first foldback bond FB1 (307), for example by bonding a fourth section 14 of the first bonding wire on the second section 12 of the first bonding wire 1.

The electrical connection 200, 200a in accordance with various embodiments may be completed by cutting a tail of the first bonding wire 1 (308).

In various embodiments, more than two stretches of wire, e. g., wire loops, may be arranged between the first contact element 210 and the second contact element 220, for example three or more stretches of the first wire 1, a second wire 2 (which may be formed by a newly attached portion of the first wire 1 or by a different wire), or a combination of the first wire 1 and the second wire 2 (and optionally further wires).

Some of these embodiments are described in the processes 309 to 311 of FIG. 3, which describes an arrangement of a third wire loop (resulting electrical connections 200, 200b, 200c are shown in FIGS. 2B and 2C), and in FIG. 4, which shows a flow diagram 400 of a method of forming an electrical connection 200, 200d, 200e that has four stretches of wire between the first contact element 210 and the second contact element 220.

As further described in FIG. 3, a further wire bond, e. g., a ball bond, may be formed, for example using a second free air ball, for example on the first stitch bond, e. g. on a fifth section 15 of the first bonding wire 1 that had been arranged to be adjacent to the third section 13 of the first bonding wire 1 (309).

The further wire bond may be formed by attaching a sixth section 26 of a second bonding wire 2 onto the first stitch bond, e. g. onto the fifth section 15 of the first bonding wire 1.

From the position of the first stitch bond on the second contact element 220, the third wire loop may be formed (310), for example extending towards the first foldback bond FB1.

A third stitch bond may be formed on the first foldback bond FB1 and the second stitch bond and the fourth section 14 on the first contact element 210 (311).

The resulting (three-wire) electrical connection 200, 200b is shown in FIG. 2B.

As an alternative to the processes 309 to 311, after the tail cut (308), the second ball bond may be formed on the first foldback bond FB1 (on the second stitch, on the fourth section 14, on the first contact element 210), the third wire loop may extend towards the first stitch bond on the second contact element 220. The third wire stitch may be formed on the first stitch bond (on the fifth section 15).

The resulting (three-wire) electrical connection 200, 200c is shown in FIG. 2C.

In various embodiments, four or more wires may be arranged to connect the first contact element 210 and the second contact element 220.

A flow diagram 400 of a method of forming an electrical connection is shown in FIG. 4. Some of the processes correspond to those described in context with FIG. 3, so a repeated description may have been omitted.

Processes 401 to 407 may correspond to the processes 301 to 307, and process 408 may correspond to process 309. However, in order to allow for the arrangement of a fourth wire, the second ball bond may be converted to a second foldback bond FB2, in a similar way like the first foldback bond FB1, by forming a kink (using a sixth section 26 of the second wire 2 and an eighth section 28 of the second wire arranged vertically adjacent to the sixth section 26) and pressing on the kink (409).

Process 410 may correspond to the process 310, and process 411 may correspond to the process 311. A third stitch bond that may be formed may bond a seventh section 27 of the second wire 2 to the fourth section 14 and/or the second section 12 of the first wire 1.

More of the second wire 2 may, after the forming the third stitch bond, be released (with or without an adjustment of the angle α) (412) and may be extended, for example as a fourth wire loop, towards the second contact element 220 and the second foldback bond FB2 (413).

A fourth stitch bond may in various embodiments be formed on the second foldback bond FB2 (414).

A tail cut may end the second bonding process (415). FIG. 2D shows a resulting electrical connection 200, 200d in accordance with various embodiments.

Embodiments having the ball bond (formed from the sixth section 26 of the second wire 2) or the foldback bond (formed from the sixth section 26 and the eighth section 28 of the second bonding wire) on the first stitch bond may be beneficial in that the ball bond or the foldback bond, respectively, may additionally secure the stitch bond (the third section 13 and the fifth section of the first wire 1) on the second contact element 220.

In various embodiments, as an alternative to processes 408 to 415, the second foldback bond FB2 may be formed on the first foldback bond FB1, and the third stitch bond may be formed on the first angle-adjusted stitch bond (not shown).

As a further alternative, only the first wire 1 may be used for forming the four wire loops extending one on top of the other between the first contact element 1 and the second contact element 2. A resulting embodiment for an electrical connection 200, 200e is shown in FIG. 2E.

The first foldback bond FB1 may be formed on the first contact element 210 as described above, for example in context with FIG. 3.

Also, the first stitch bond on the second contact element 220 may be formed as described above for the case including the angle adjustment.

After the first stitch bond that bonds the third section 13 onto the second contact element 220, further stitch bonds may be alternatingly formed on the first contact element 210 and the second contact element 220 on the respective previously formed bonds, wherein an angle adjustment is performed for the stitch bond if a further wire section is supposed to be arranged on top of it.

Using either the continuous back-and-forth bonding of a single wire or the arranging of newly started wires using a foldback bond, even more than four wires may be arranged as part of the wire stack that connects the first contact element 210 and the second contact element 220.

This concept may enable more wires between two contact elements for high current performance.

The method of forming an electrical connection between a first contact element and a second contact element may arrange wire loops one on top of the other by providing the wire bonds with a flat top surface for receiving a further wire bond thereon. The first pair of wire loops may include a flat-top ball bond (formed as a foldback bond) on the first contact element, a stitch bond on the second contact element, and the wire brought back and bonded to the flat-top ball bond. The stitch bond(s) may be angle adjusted if they are to receive another bond on their top surface.

As mentioned above, in some cases, the second contact element 220 (and/or the first contact element 210) may be sensitive to the pressure exerted by the bonding tool 330.

In such a case, the contact element 210, 220 may be configured to include a padding element 250, for example as shown in FIG. 2F.

The padding element 250 may be formed from a free air ball, which may pad or cushion the pressure.

The padding element 250 may be combined with any of the above described embodiments. In other words, the padding element 250 may be provided on the second element of each of the embodiments of FIGS. 2A to 2E.

Various examples will be illustrated in the following:

Example 1 is a method of forming an electrical connection. The method may include: forming a first foldback bond on a first contact element by bonding a first section of a first bonding wire to the first contact element, folding the first bonding wire to arrange a second section of the first bonding wire over the bonded first section, and pressing the second section onto the first section, bonding a third section of the first bonding wire to a second contact element, and bonding a fourth section of the first bonding wire onto the first foldback bond.

In Example 2, the subject-matter of Example 1 may optionally include that the first foldback bond includes a flat top surface section for receiving the fourth section.

In Example 3, the subject-matter of Example 1 or 2 may optionally include that the bonding the first section of the first bonding wire to the first contact element includes melting the first section of the first bonding wire to form a free air ball and attaching the free air ball to the first contact element.

In Example 4, the subject-matter of any of Examples 1 to 3 may optionally include that the bringing the first bonding wire back to the first foldback bond includes forming a loop with the first bonding wire.

In Example 5, the subject-matter of any of Examples 1 to 4 may optionally include that the bringing the first bonding wire back to the first foldback bond includes decreasing an angle α between the first bonding wire and the second contact element to arrange a fifth section of the first bonding wire vertically adjacent to or in contact with the third section.

In Example 6, the subject-matter of Example 5 may optionally include that decreasing the angle α between the first bonding wire and the second contact element includes pulling the first bonding wire towards the first contact element and/or pressing the first bonding wire towards the second contact element.

In Example 7, the subject-matter of any of Examples 1 to 6 may optionally include that the free end of the first bonding wire is still attached to the third section of the first bonding wire while the free end is being brought back to the first foldback bond.

In Example 8, the subject-matter of any of Examples 1 to 7 may optionally include that the second contact element includes a padding element formed on a second contact pad or lead, wherein the third section of the first bonding wire is bonded to the padding element.

In Example 9, the subject-matter of Example 8 may optionally include that the padding element is a bump formed by melting a portion of a third bonding wire to form a second free air ball and bonding the second free air ball to the second contact pad or lead.

In Example 10, the subject-matter of any of Examples 5 to 9 may optionally further include bonding a sixth section of a second bonding wire onto the fifth section and bonding a seventh section of the second bonding wire onto the fourth section, or bonding a sixth section of a second bonding wire onto the fourth section and bonding a seventh section of the second bonding wire onto the sixth section.

In Example 11, the subject-matter of Example 10 may optionally include that the bonding the sixth section onto the fourth section or the fifth section includes melting the sixth section of the second bonding wire to form a third free air ball and attaching the third free air ball to the fourth section or the fifth section, respectively.

In Example 12, the subject-matter of Example 11 may optionally further include bonding an eighth section of the second bonding wire to the sixth section.

In Example 13, the subject-matter of Example 11 may optionally further include forming a second foldback bond on the fourth section or on the fifth section by bonding the sixth section of the second bonding wire to the fourth section or on the fifth section, respectively, folding the second bonding wire to arrange the eighth section of the second bonding wire over the bonded sixth section, and pressing the eighth section onto the sixth section.

In Example 14, the subject-matter of Example 13 may optionally further include bonding a ninth section of the second bonding wire onto the eighth section.

In Example 15, the subject-matter of any of Examples 5 to 9 may optionally further include alternating between the first contact element and the second contact element for bonding consecutive portions of the first bonding wire alternatingly on top of the fourth section of the first bonding wire and the fifth section of the first bonding wire, respectively.

Example 16 is an electrical connection. The electrical connection may include a first contact element, a second contact element, a first foldback bond on the first contact element including a first section of a first bonding wire bonded to the first contact element, and a second section of the first bonding wire that is folded back over and bonded onto the bonded first section, a third section of the first bonding wire bonded to the second contact element, and a fourth section of the first bonding wire bonded onto the first foldback bond.

In Example 17, the subject-matter of Example 16 may optionally include that the first foldback bond includes a flat top surface to which the fourth section is bonded.

In Example 18, the subject-matter of Example 16 or 17 may optionally include that the first contact element and/or the second contact element are selected from a group of contact elements, the group consisting of: a chip contact pad, a leadframe, a lead, a clip, and a contact area of a printed circuit board.

In Example 19, the subject-matter of any of Examples 16 to 18 may optionally include that the first bonding wire forms a loop between the third section and the fourth section.

In Example 20, the subject-matter of any of Examples 16 to 19 may optionally include that the first bonding wire further includes a fifth section that is arranged vertically adjacent to or in contact with the third section.

In Example 21, the subject-matter of Example 20 may optionally include that an angle α between the fifth section of the first bonding wire and the second contact element is an acute angle.

In Example 22, the subject-matter of any of Examples 16 to 19 may optionally include that the first bonding wire includes or consists of at least one of a group of metals, the group consisting of: copper, gold, and silver.

In Example 23, the subject-matter of any of Examples 16 to 22 may optionally include that the second contact element includes a padding element, and that the third section of the first bonding wire is bonded to the padding element.

In Example 24, the subject-matter of Example 23 may optionally include that the padding element is formed from bonding wire, optionally from the first bonding wire.

In Example 25, the subject-matter of Example 23 or 24 may optionally include that a material of the padding element is identical to a material of the first bonding wire.

In Example 26, the subject-matter of any of Examples 20 to 25 may optionally further include a sixth section of a second bonding wire bonded onto the fifth section and a seventh section of the second bonding wire bonded onto the fourth section, or a sixth section of a second bonding bonded onto the fourth section and a seventh section of the second bonding wire bonded onto the fifth section.

In Example 27, the subject-matter of Example 26 may optionally include that a material of the second bonding wire is identical to a material of the first bonding wire.

In Example 28, the subject-matter of Example 27 may optionally further include that an eighth section of the second bonding wire bonded onto the sixth section.

In Example 29, the subject-matter of any of Examples 20 to 28 may optionally further include a second foldback bond including a sixth section of the second bonding wire bonded to the fifth section or to the fourth section, and an eighth section of the second bonding wire that is folded back over and bonded onto the bonded sixth section.

In Example 30, the subject-matter of Example 29 may optionally further include that a ninth section of the second bonding wire bonded onto the eighth section.

In Example 31, the subject-matter of any of Examples 21 to 25 may optionally include that consecutive portions of the first bonding wire that are bonded alternatingly between the first contact element on top of the fourth section of the first bonding wire and the second contact element on top of the fifth section of the first bonding wire, respectively.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of forming an electrical connection, the method comprising:
forming a first foldback bond on a first contact element by bonding a first section of a first bonding wire to the first contact element, folding the first bonding wire to arrange a second section of the first bonding wire over the bonded first section, and pressing the second section onto the first section;
bonding a third section of the first bonding wire to a second contact element; and
bonding a fourth section of the first bonding wire onto the first foldback bond.

2. The method of claim 1, wherein the first foldback bond comprises a flat top surface section for receiving the fourth section.

3. The method of claim 1, wherein bonding the first section of the first bonding wire to the first contact element comprises:
melting the first section of the first bonding wire to form a free air ball; and
attaching the free air ball to the first contact element.

4. The method of claim 1, wherein bringing the first bonding wire back to the first foldback bond comprises forming a loop with the first bonding wire.

5. The method of claim 1, wherein bringing the first bonding wire back to the first foldback bond comprises decreasing an angle α between the first bonding wire and the second contact element to arrange a fifth section of the first bonding wire vertically adjacent to or in contact with the third section.

6. The method of claim 5, wherein decreasing the angle α between the first bonding wire and the second contact element comprises pulling the first bonding wire towards the first contact element and/or pressing the first bonding wire towards the second contact element.

7. The method of claim 5, further comprising:
bonding a sixth section of a second bonding wire onto the fifth section and bonding a seventh section of the second bonding wire onto the fourth section; or
bonding a sixth section of a second bonding wire onto the fourth section and bonding a seventh section of the second bonding wire onto the sixth section.

8. The method of claim 7, wherein bonding the sixth section onto the fourth section or the fifth section comprises:
melting the sixth section of the second bonding wire to form a third free air ball; and
attaching the third free air ball to the fourth section or the fifth section, respectively.

9. The method of claim 8, further comprising:
bonding an eighth section of the second bonding wire to the sixth section.

10. The method of claim 8, further comprising:
forming a second foldback bond on the fourth section or on the fifth section by bonding the sixth section of the second bonding wire to the fourth section or on the fifth section, respectively;
folding the second bonding wire to arrange the eighth section of the second bonding wire over the bonded sixth section; and
pressing the eighth section onto the sixth section.

11. The method of claim 10, further comprising:
bonding a ninth section of the second bonding wire onto the eighth section.

12. The method of claim 5, further comprising:
alternating between the first contact element and the second contact element for bonding consecutive portions of the first bonding wire alternatingly on top of the fourth section of the first bonding wire and the fifth section of the first bonding wire, respectively.

13. The method of claim 1, wherein the free end of the first bonding wire is still attached to the third section of the first bonding wire while the free end is being brought back to the first foldback bond.

14. The method of claim 1, wherein the second contact element comprises a padding element formed on a second contact pad or lead, and wherein the third section of the first bonding wire is bonded to the padding element.

15. The method of claim 14, wherein the padding element is a bump formed by melting a portion of a third bonding wire to form a second free air ball and bonding the second free air ball to the second contact pad or lead.

16. An electrical connection, comprising:
a first contact element;
a second contact element;
a first foldback bond on the first contact element comprising a first section of a first bonding wire bonded to the first contact element, and a second section of the first bonding wire that is folded back over and bonded onto the bonded first section;
a third section of the first bonding wire bonded to the second contact element; and
a fourth section of the first bonding wire bonded onto the first foldback bond.

17. The electrical connection of claim 16, wherein the first foldback bond comprises a flat top surface to which the fourth section is bonded.

18. The electrical connection of claim 16, wherein the first contact element and/or the second contact element is selected from the group of contact elements consisting of: a chip contact pad; a leadframe; a lead; a clip; and a contact area of a printed circuit board.

19. The electrical connection of claim 16, wherein the first bonding wire forms a loop between the third section and the fourth section.

20. The electrical connection of claim 16, wherein the first bonding wire further comprises a fifth section that is arranged vertically adjacent to or in contact with the third section.

21. The electrical connection of claim 20, wherein an angle α between the fifth section of the first bonding wire and the second contact element is an acute angle.

22. The electrical connection of claim 20, further comprising:
a sixth section of a second bonding wire bonded onto the fifth section and a seventh section of the second bonding wire bonded onto the fourth section; or
a sixth section of a second bonding bonded onto the fourth section and a seventh section of the second bonding wire bonded onto the fifth section.

23. The electrical connection of claim 22, wherein a material of the second bonding wire is identical to a material of the first bonding wire.

24. The electrical connection of claim 23, further comprising:
an eighth section of the second bonding wire bonded onto the sixth section.

25. The electrical connection of claim 20, further comprising:
a second foldback bond comprising a sixth section of the second bonding wire bonded to the fifth section or to the fourth section; and
an eighth section of the second bonding wire that is folded back over and bonded onto the bonded sixth section.

26. The electrical connection of claim 25, further comprising:
a ninth section of the second bonding wire bonded onto the eighth section.

27. The electrical connection of claim 21, wherein consecutive portions of the first bonding wire are bonded alternatingly between the first contact element on top of the fourth section of the first bonding wire and the second contact element on top of the fifth section of the first bonding wire, respectively.

28. The electrical connection of claim 16, wherein the first bonding wire comprises or consists of at least one of a group of metals selected from the group consisting of:
copper; gold; and silver.

29. The electrical connection of claim 16, wherein the second contact element comprises a padding element, and wherein the third section of the first bonding wire is bonded to the padding element.

30. The electrical connection of claim 29, wherein the padding element is formed from bonding wire, optionally from the first bonding wire.

31. The electrical connection of claim 29, wherein a material of the padding element is identical to a material of the first bonding wire.
